(19) United States
(12) Patent Application Publication
(10) Pub. No.: US 2025/0040168 A1
(43) Pub. Date: Jan. 30, 2025

(54) SELF-ALIGNED GATE CONTACT OVER LOCALLY RAISED GATE

(71) Applicant: INTERNATIONAL BUSINESS MACHINES CORPORATION, ARMONK, NY (US)

(72) Inventors: Ruilong Xie, Niskayuna, NY (US); Lawrence A. Clevenger, Saratoga Springs, NY (US); HUIMEI ZHOU, Albany, NY (US); Min Gyu Sung, Latham, NY (US)

(21) Appl. No.: 18/360,856

(22) Filed: Jul. 28, 2023

(51) Int. Cl. H01L 29/775; H01L 27/088; H01L 29/06; H01L 29/417; H01L 29/423; H01L 29/786

(52) U.S. Cl. CPC H01L 29/775; H01L 27/088; H01L 29/0673; H01L 29/41725; H01L 29/42392; H01L 29/78696

(57) ABSTRACT

Embodiments of present invention provide a semiconductor structure. The semiconductor structure includes a gate structure with a first portion having a first top surface and a second portion having a second top surface, the first top surface being above the second top surface; a dielectric cap layer on top of the second portion of the gate structure, the first portion of the gate structure being embedded in the dielectric cap layer; and a gate contact being above and substantially aligned with the first portion of the gate structure. A method of forming the same is also provided.

### BACKGROUND

The present application relates to manufacturing of semiconductor integrated circuits. More particularly, it relates to forming gate contact of nanosheet transistor and the structure formed thereby.

As semiconductor industry moves towards smaller node, for example 3-nm node and beyond, field-effect-transistors (FETs) such as nanosheet transistors are aggressively scaled to fit into reduced footprint or real estate dictated by the node size. With constantly increasing in device density, spaces for forming source/drain contacts and gate contact of transistors become smaller, resulting in concerns of potential short between source/drain contacts and the gate contact.

### SUMMARY

Embodiments of present invention provide a semiconductor structure. The semiconductor structure includes a gate structure with a first portion having a first top surface and a second portion having a second top surface, the first top surface being above the second top surface; a dielectric cap layer on top of the second portion of the gate structure, the first portion of the gate structure being embedded in the dielectric cap layer; and a gate contact being above and substantially aligned with the first portion of the gate structure.

In one embodiment, the semiconductor structure further includes a source/drain contact adjacent to the gate structure, wherein the source/drain contact has a top surface that is below the first top surface of the first portion of the gate structure.

In another embodiment, the semiconductor structure further includes a sidewall spacer at a sidewall of the gate structure and in between the gate structure and the source/drain contact, wherein a height of the sidewall spacer is greater than a height of the source/drain contact.

In one aspect, an upper portion of the sidewall spacer above the source/drain contact has a non-uniform thickness.

In yet another embodiment, the semiconductor structure further includes a via contact contacting the top surface of the source/drain contact, wherein a top surface of the via contact is coplanar with a top surface of the gate contact.

In one aspect, the gate structure surrounds a set of nanosheets, and the source/drain contact is above an epitaxial source/drain region formed at an end of the set of nanosheets.

In another aspect, cross-sections of the via contact and the gate contact, made perpendicular to a length direction of the gate structure, do not overlap with each other.

Embodiments of present invention also provide a method of forming a semiconductor structure. The method includes forming a raw gate structure surrounding a set of nanosheets; recessing a portion of the raw gate structure to create a gate structure, the gate structure including a first portion having a first height and a second portion having a second height, the first height being greater than the second height; exposing an epitaxial source/drain region adjacent to the gate structure; forming a source/drain contact on top of the epitaxial source/drain region; recessing the source/drain contact such that a top surface of the source/drain contact becomes lower than a top surface of the first portion of the gate structure; forming a gate contact contacting the first portion of the gate structure; and forming a via contact contacting the source/drain contact.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D to FIGS. 13A, 13B, 13C, and 13D are demonstrative illustrations of different cross-sectional views and schematic top view of a semiconductor structure in several steps of manufacturing thereof according to embodiments of present invention; and

FIG. 14 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

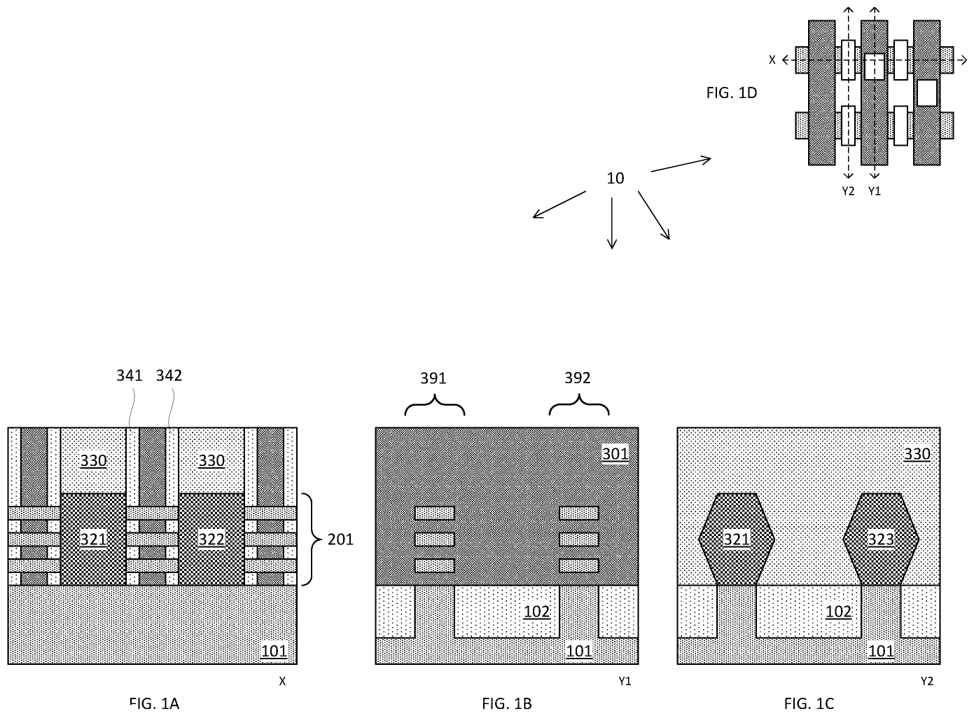

FIGS. 1A, 1B, 1C, and 1D are demonstrative illustrations of different cross-sectional views and schematic top view of a semiconductor structure 10 in a step of manufacturing thereof according to one embodiment of present invention. Here, the semiconductor structure 10 is demonstratively illustrated to include nanosheet transistors. However, embodiments of present invention are not limited in this aspect and may be applied to form semiconductor structures with other types of transistors and/or active devices.

More specifically, FIG. 1A illustrates a cross-sectional view of the semiconductor structure 10 along a dashed line X as indicated in FIG. 1D. In other words, FIG. 1A is a view of cross-section made across the S/D regions and the gate in a direction parallel to the longitudinal direction of the nanosheets. FIG. 1B illustrates a cross-sectional view of the semiconductor structure 10 along a dashed line Y1 as indicated in FIG. 1D. In other words, FIG. 1B is a view of cross-section made across the gate in a direction parallel to the gate. FIG. 1C illustrates a cross-sectional view of the semiconductor structure 10 along a dashed line Y2 as indicated in FIG. 1D. In other words, FIG. 1C is a view of cross-section made across the S/D region in a direction parallel to the gate. FIG. 1D is a schematic top view of the semiconductor structure 10. Here, for the sole purpose of better understanding of FIGS. 1A, 1B, and 1C, FIG. 1D may illustrate only key elements such as, for example, nanosheets, gates, and S/D regions of the semiconductor structure 10 and may illustrate additional elements that are yet to be formed. Other elements, such as dielectric cap layer, sidewall spacers, etc., may not necessarily be illustrated in FIG. 1D to the extent that their omitting from the drawing does not hinder the understanding of FIGS. 1A, 1B, and 1C, even though some of these elements do exist.

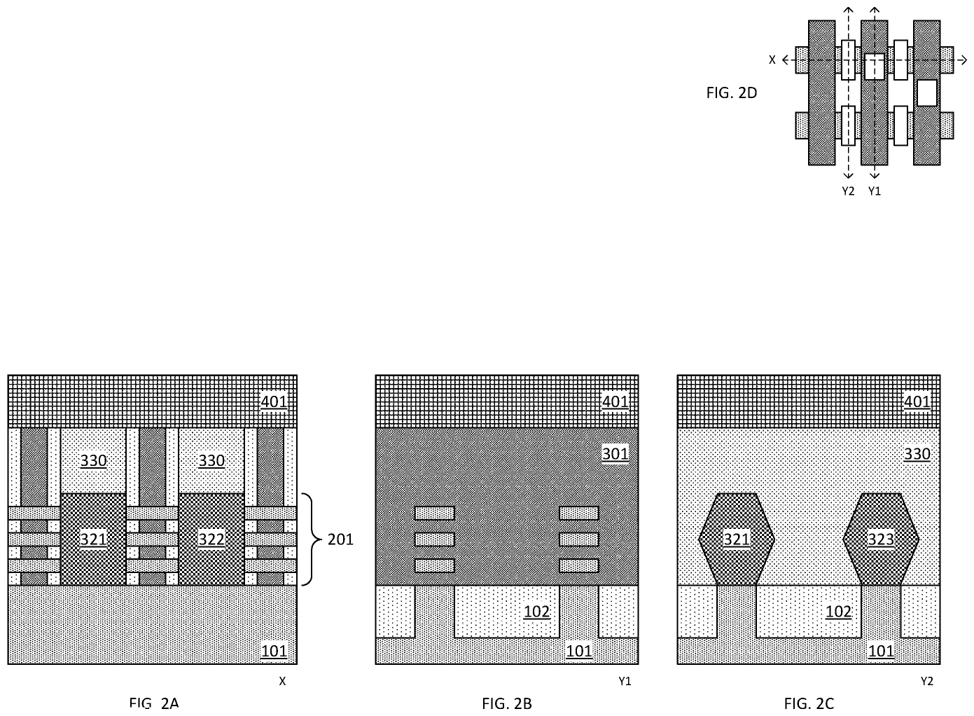

Similarly, FIGS. 2A, 2B, 2C, and 2D to FIGS. 13A, 13B, 13C, and 13D illustrate cross-sectional reviews and schematic top view of the semiconductor structure 10, at various manufacturing stages, in manners corresponding to FIGS. 1A, 1B, 1C, and 1D.

Embodiments of present invention provide forming, receiving, or providing the semiconductor structure 10 that includes a substrate 101 with a first transistor 391 and a second transistor 392 formed on top of the substrate 101. As a non-limiting example, the first and the second transistor 391 and 392 may be nanosheet transistors. A set of shallow-trench-isolations (STIs) 102 may be formed in the substrate 101 that electronically insulates the first transistor 391 from the second transistor 392.

More specifically, the first transistor 391 may include a stack of nanosheets 201, a raw gate structure 301 surrounding the stack of nanosheets 201, and a first source/drain (S/D) region 321 and a second S/D region 322 closely placed next to the raw gate structure 301. For example, the first S/D region 321 may be separated from the raw gate structure 301 by a first sidewall spacer 341 and the second S/D region 322 may be separated from the raw gate structure 301 by a second sidewall spacer 342. The first and the second sidewall spacer 341 and 342 may be very thin to have a thickness ranging from about 5 nm to about 8 nm. The first S/D region 321 and the second S/D region 322 may be epitaxially formed at the two ends of the stack of nanosheets 201 and thus may be referred to as epitaxial S/D regions. An interlevel dielectric layer (IDL) 330 may be formed on top of the first and the second epitaxial S/D region 321 and 322.

Similarly, the second transistor 392 may include a stack of nanosheets, the raw gate structure 301 surrounding the stack of nanosheets, and a third epitaxial S/D region 323 and a fourth epitaxial S/D region (not shown) at the two ends of the stack of nanosheets.

FIGS. 2A, 2B, 2C, and 2D are demonstrative illustrations of different cross-sectional views and schematic top view of the semiconductor structure 10 in a step of manufacturing thereof according to one embodiment of present invention. More particularly, following the step illustrated in FIGS. 1A, 1B, 1C, and 1D, embodiments of present invention provide forming a dummy gate contact on top of the raw gate structure 301. In doing so, embodiments of present invention provide forming a sacrificial layer 401 on top of the raw gate structure 301 and the IDL 330. The sacrificial layer 401 may be a layer of silicon-carbide (SiC), silicon-oxycarbide (SiOC), aluminum-oxide (AlOx), and/or other suitable materials, and may be formed through a deposition process such as, for example, a chemical-vapor-deposition (CVD) process, a physical-vapor-deposition (PVD) process, and/or an atomic-layer-deposition (ALD) process. The sacrificial layer 401 may be formed to have a thickness ranging from about 20 nm to about 60 nm.

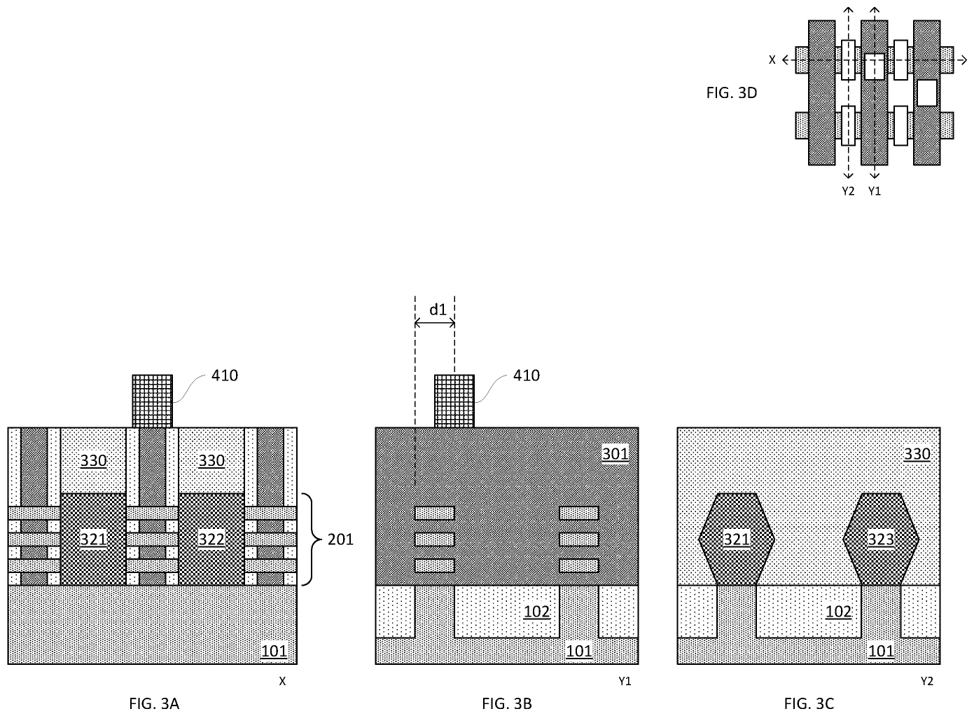

FIGS. 3A, 3B, 3C, and 3D are demonstrative illustrations of different cross-sectional views and schematic top view of the semiconductor structure 10 in a step of manufacturing thereof according to one embodiment of present invention. More particularly, following the step illustrated in FIGS. 2A, 2B, 2C, and 2D, embodiments of present invention provide patterning the sacrificial layer 401 through a lithographic patterning and etching process to form a dummy gate contact 410. The dummy gate contact 410 may entirely cover the raw gate structure 301, lengthwise, as is illustrated in FIG. 3A and may possibly cover a portion of the first sidewall spacer 341 and/or a portion of the second sidewall spacer 342. On the other hand, the dummy gate contact 410 may cover only a portion of the raw gate structure 301, widthwise, as is illustrated in FIG. 3B. In one embodiment, a central axis of the dummy gate contact 410 may have an offset d1 in distance from a longitudinal edge of the set of nanosheets 201. For example, the dummy gate contact 410 may be placed asymmetric with respect to the set of nanosheets 201. As is illustrated in FIG. 3B, the dummy gate contact 410 may be placed more towards the right-side of the set of nanosheets 201.

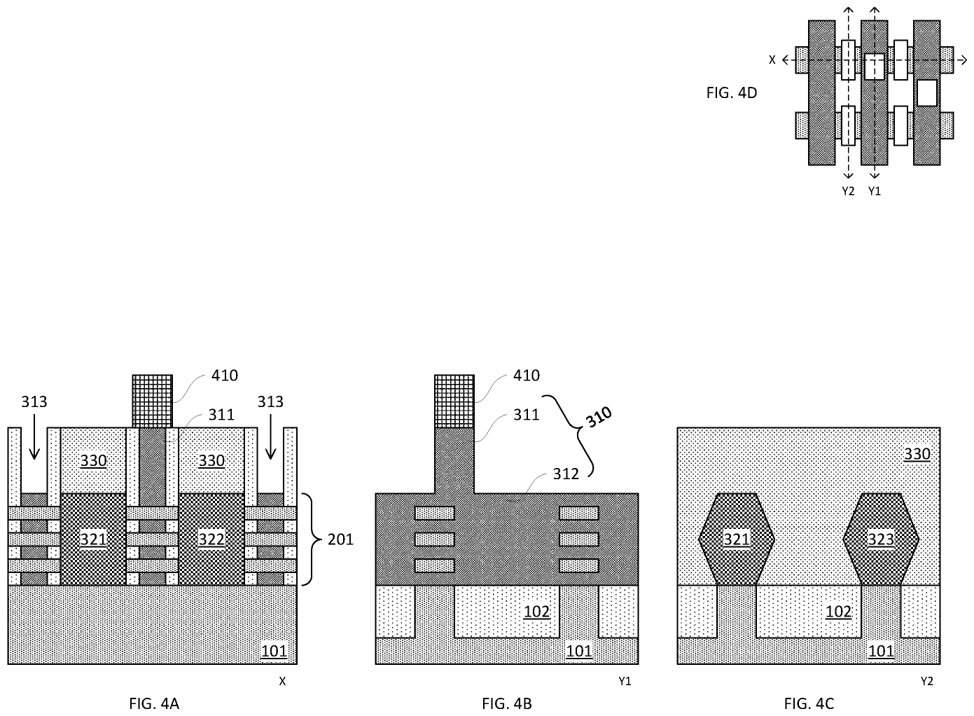

FIGS. 4A, 4B, 4C, and 4D are demonstrative illustrations of different cross-sectional views and schematic top view of the semiconductor structure 10 in a step of manufacturing thereof according to one embodiment of present invention. More particularly, following the step illustrated in FIGS. 3A, 3B, 3C, and 3D, embodiments of present invention provide recessing, in a directional etching process, the raw gate structure 301 with the dummy gate contact 410 covering, therefore protecting, a portion of the raw gate structure 301. The recessing process thus creates a gate structure 310 that includes a first portion 311 and a second portion 312. By the nature that the first portion 311 is created using the dummy gate contact 410 as an etch mask in a directional etching process, the dummy gate contact 410 is substantially aligned with the first portion 311 of the gate structure 310.

The first portion 311 of the gate structure 310 has a first top surface and the second portion 312 of the gate structure 310 has a second top surface. Since the second portion 312 is recessed from the raw gate structure 301, the second top surface of the second portion 312 is below the first top surface of the first portion 311. In other words, the first top surface of the first portion 311 is above the second top surface of the second portion 312. Additionally, as is illustrated in FIG. 4A, raw gate structures that are not covered by the dummy gate contact 410 may be recessed to have openings 313 created between sidewall spacers.

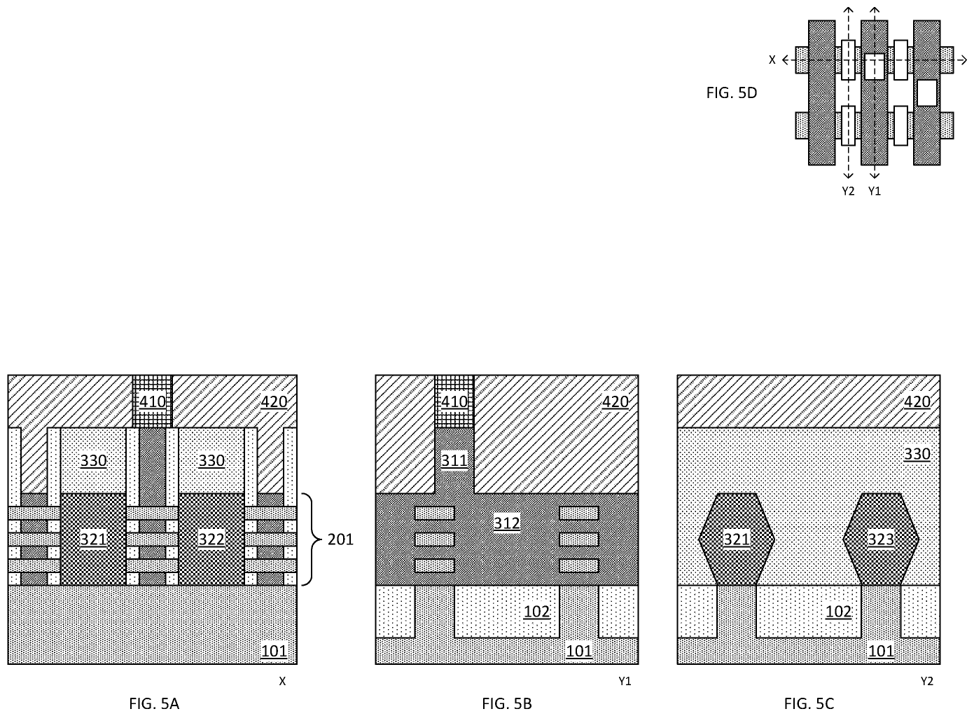

FIGS. 5A, 5B, 5C, and 5D are demonstrative illustrations of different cross-sectional views and schematic top view of the semiconductor structure 10 in a step of manufacturing thereof according to one embodiment of present invention. More particularly, following the step illustrated in FIGS. 4A, 4B, 4C, and 4D, embodiments of present invention provide forming a dielectric layer 420, such as silicon-nitride (SiN) or silicon-oxide (SiOx), on top of and covering the gate structure 310 including the first portion 311 and the second portion 312. The dielectric layer 420 may be formed through, for example, a deposition process and may fill the openings 313 and cover the dummy gate contact 410 as well. After the deposition of the dielectric layer 420, a chemical-mechanical-polishing (CMP) process may be applied to planarize a top surface of the dielectric layer 420 until, for example, the dummy gate contact 410 is exposed.

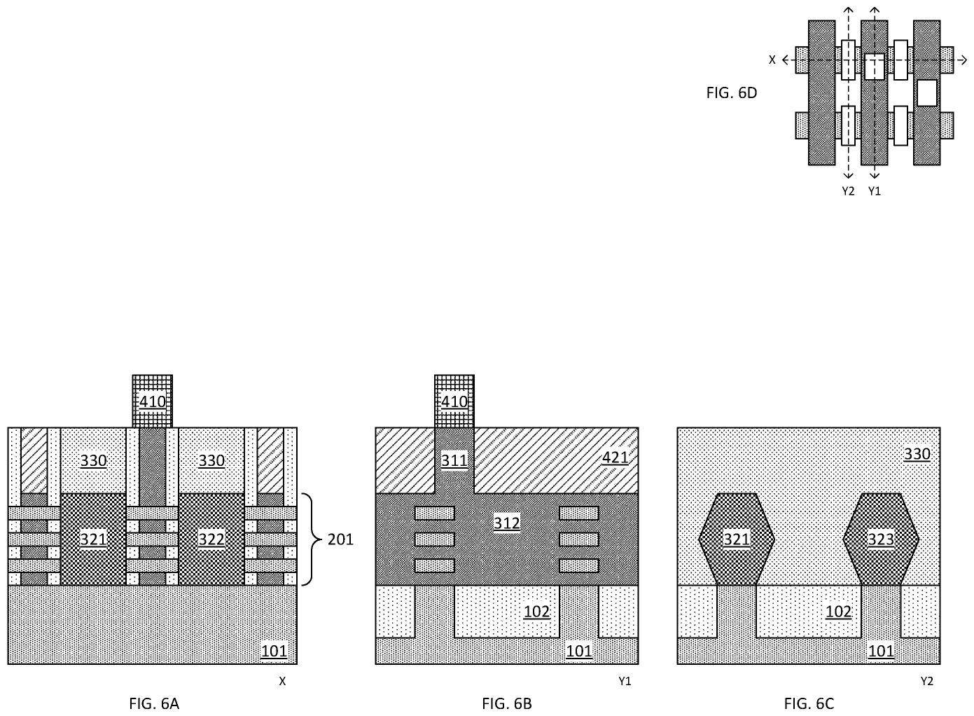

FIGS. 6A, 6B, 6C, and 6D are demonstrative illustrations of different cross-sectional views and schematic top view of the semiconductor structure 10 in a step of manufacturing thereof according to one embodiment of present invention. More particularly, following the step illustrated in FIGS. 5A, 5B, 5C, and 5D, embodiments of present invention provide recessing the dielectric layer 420 to form a dielectric cap layer 421 covering the second portion 312 of the gate structure 310. The dielectric cap layer 421, formed from the dielectric layer 420, may continue to surround the first portion 311 of the gate structure 310. In other words, the first portion 311 of the gate structure 310 may be embedded in the dielectric cap layer 421. The recessing of the dielectric layer 420 exposes the dummy gate contact 410.

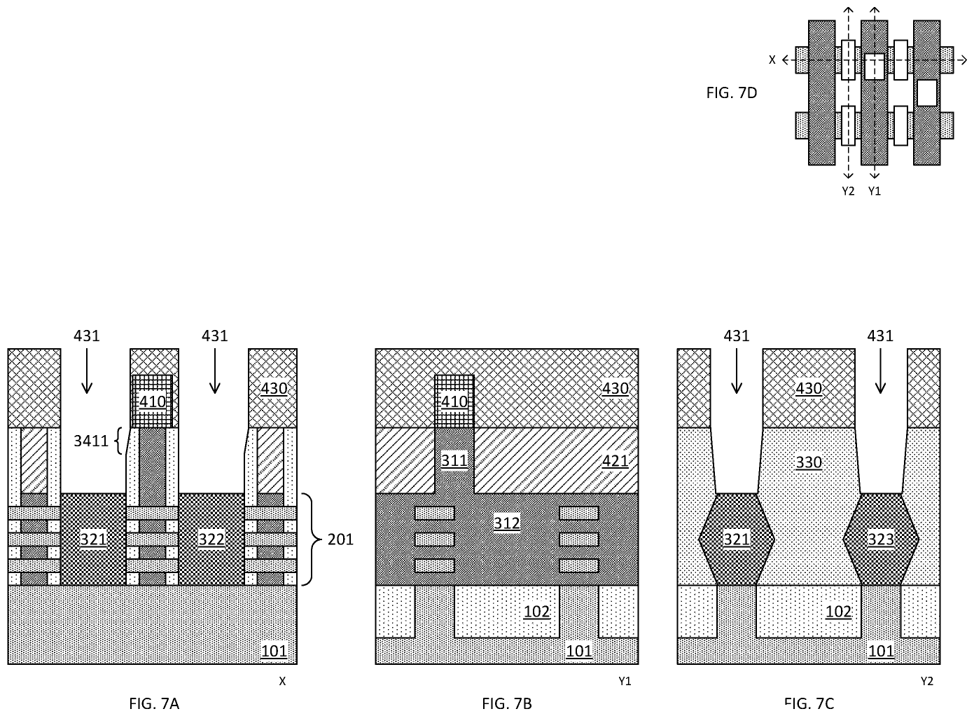

FIGS. 7A, 7B, 7C, and 7D are demonstrative illustrations of different cross-sectional views and schematic top view of the semiconductor structure 10 in a step of manufacturing thereof according to one embodiment of present invention. More particularly, following the step illustrated in FIGS. 6A, 6B, 6C, and 6D, embodiments of present invention provide forming an organic planarization layer (OPL) 430 on top of the dielectric cap layer 421, the first portion 311 of the gate structure 310, and the IDL 330. Next, through a lithographic patterning and etching process, embodiments of present invention provide creating S/D contact openings 431. The S/D contact openings 431 may be created through the OPL 430 and the IDL 330 to expose the S/D regions such as the first epitaxial S/D region 321, the second epitaxial S/D region 322, the third epitaxial S/D region 323, and the fourth epitaxial S/D region (not shown). In one embodiment, the lithographic patterning and etching process may cause an upper portion 3411 of the sidewall spacer 341 to be partially etched, due to for example misalignment of the patterning mask of the OPL 430. In other words, the upper portion 3411 of the sidewall spacer 341 may have a non-uniform thickness, whose thickness may not be sufficient to insulate a source/drain contact from the gate structure 310.

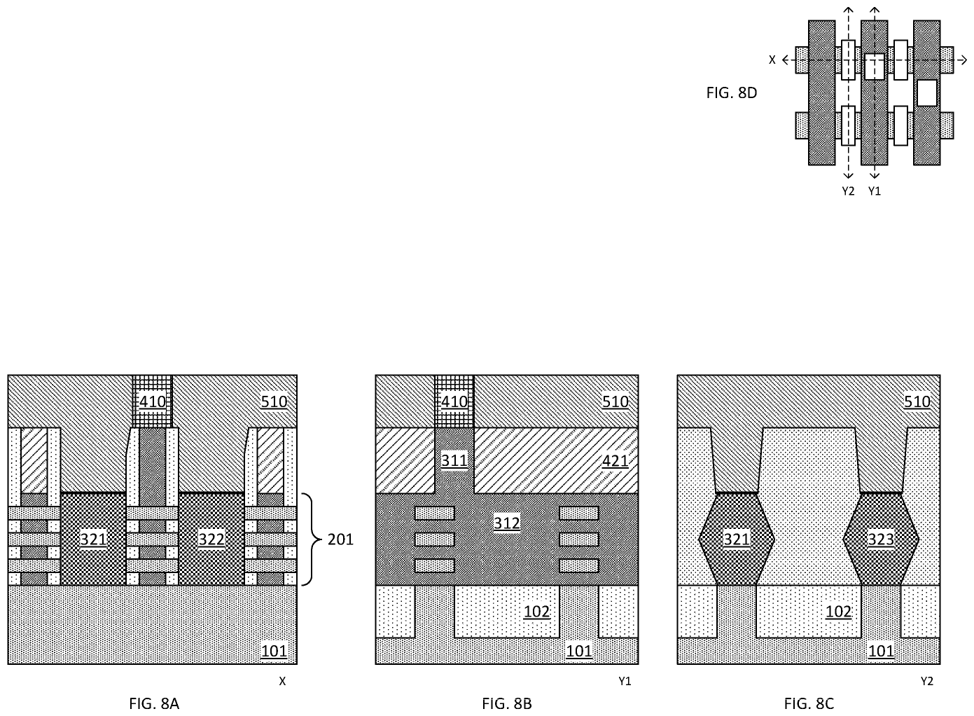

FIGS. 8A, 8B, 8C, and 8D are demonstrative illustrations of different cross-sectional views and schematic top view of the semiconductor structure 10 in a step of manufacturing thereof according to one embodiment of present invention. More particularly, following the step illustrated in FIGS. 7A, 7B, 7C, and 7D, embodiments of present invention provide lifting the OPL 430 such as, for example, through an ash process and forming a conductive material layer 510 that may fill the S/D contact openings 431 and may be formed to cover the dummy gate contact 410. In one embodiment, the height of the conductive material layer 510 may cause the dummy gate contact 410 to be embedded in the conductive material layer 510. The conductive material layer 510 may include, for example, a silicide liner layer such as Ti, a metal adhesion layer such as TiN, and conductive metal fill such as tungsten (W), copper (Cu), cobalt (Co), and/or aluminum (AI). Next, a CMP process may be applied to planarize a top surface of the conductive material layer 510. For example, CMP process may be applied until the dummy gate contact 410 is exposed.

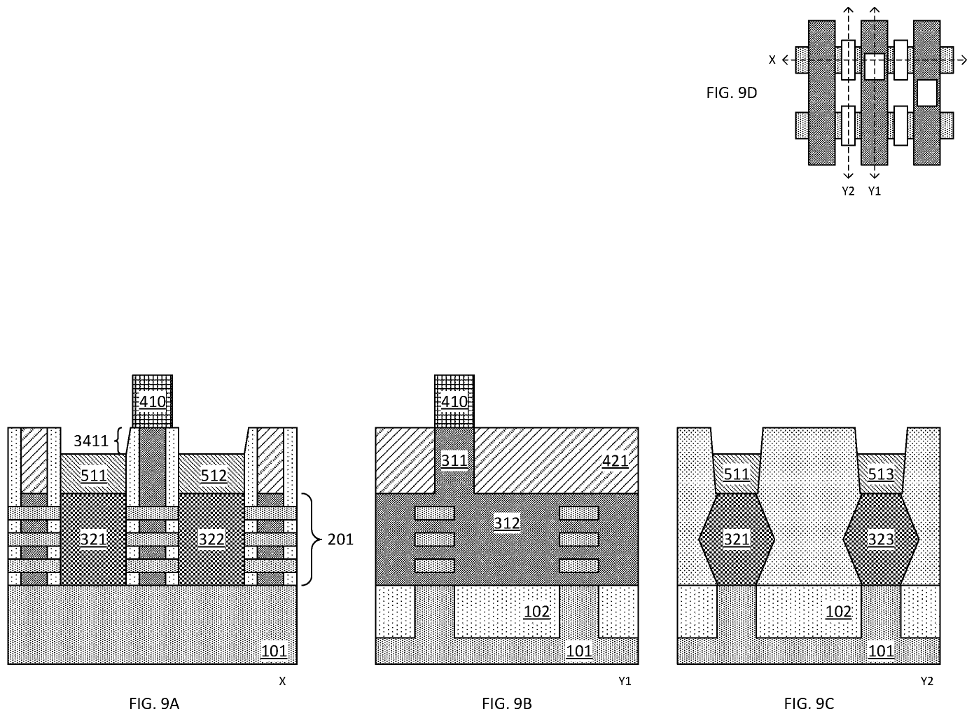

FIGS. 9A, 9B, 9C, and 9D are demonstrative illustrations of different cross-sectional views and schematic top view of the semiconductor structure 10 in a step of manufacturing thereof according to one embodiment of present invention. More particularly, following the step illustrated in FIGS. 8A, 8B, 8C, and 8D, embodiments of present invention provide recessing the conductive material layer 510 to a level below the top surface of the first portion 311 of the gate structure 310 thereby forming, for example, a source/drain contact 511 above the first epitaxial S/D region 321, a source/drain contact 512 above the second epitaxial S/D region 322, and a source/drain contact 513 above the third epitaxial S/D region 323. More particularly, the source/drain contacts 511, 512, and 513 may be formed to have a height such that they are directly adjacent to a lower portion of the sidewall spacers 341 and 342 that has a uniform thickness. In other words, the conductive material layer 510 may be recessed to a level below the upper portion 3411 of the sidewall spacers 341 and 342 that have tapered, non-uniform, and/or varying thickness, which may be caused during some preceding etching steps as being described above. The uniform and sufficient thickness of the lower portion of the sidewall spacers 341 and/or 342 reduces the chance of electric breakdown across the sidewall spacers 341 and/or 342 between, for example, the source/drain contacts 511 and/or 512 and the gate structure 310, which otherwise would be due to weak and/or inadequate thickness of the upper portion of the sidewall spacers 341 and/or 342.

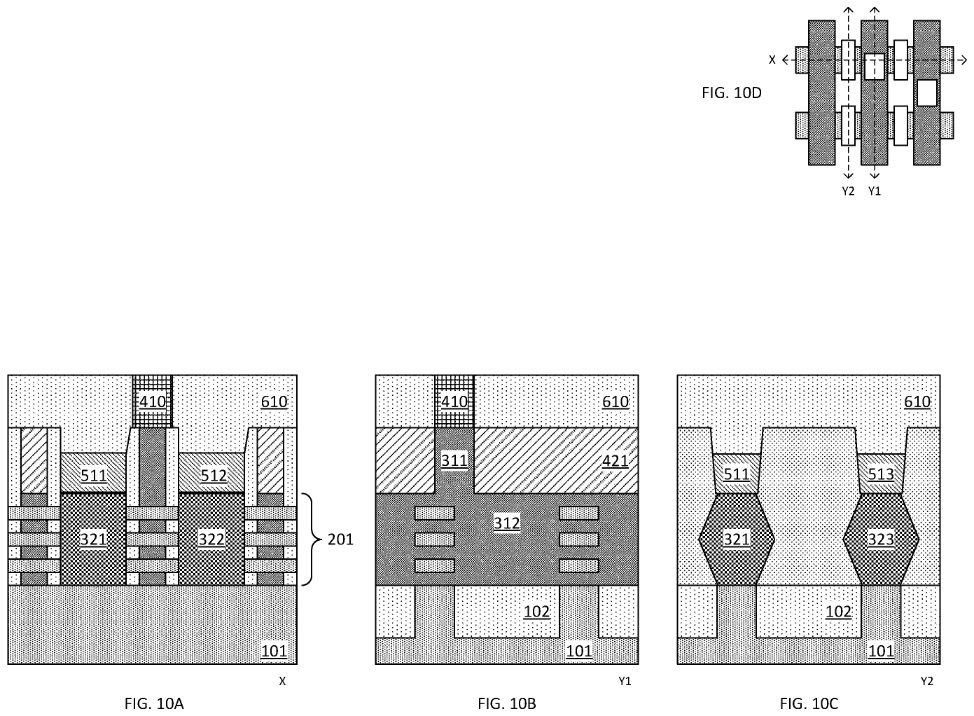

FIGS. 10A, 10B, 10C, and 10D are demonstrative illustrations of different cross-sectional views and schematic top view of the semiconductor structure 10 in a step of manufacturing thereof according to one embodiment of present invention. More particularly, following the step illustrated in FIGS. 9A, 9B, 9C, and 9D, embodiments of present invention provide forming a dielectric layer 610, for example through deposition, on top of and covering the source/drain contacts such as the source/drain contact 511, 512, and 513 and on top of and covering the dummy gate contact 410. Subsequently, a CMP process may be applied to planarize a top surface of the dielectric layer 610 until the top surface of the dummy gate contact 410 is exposed.

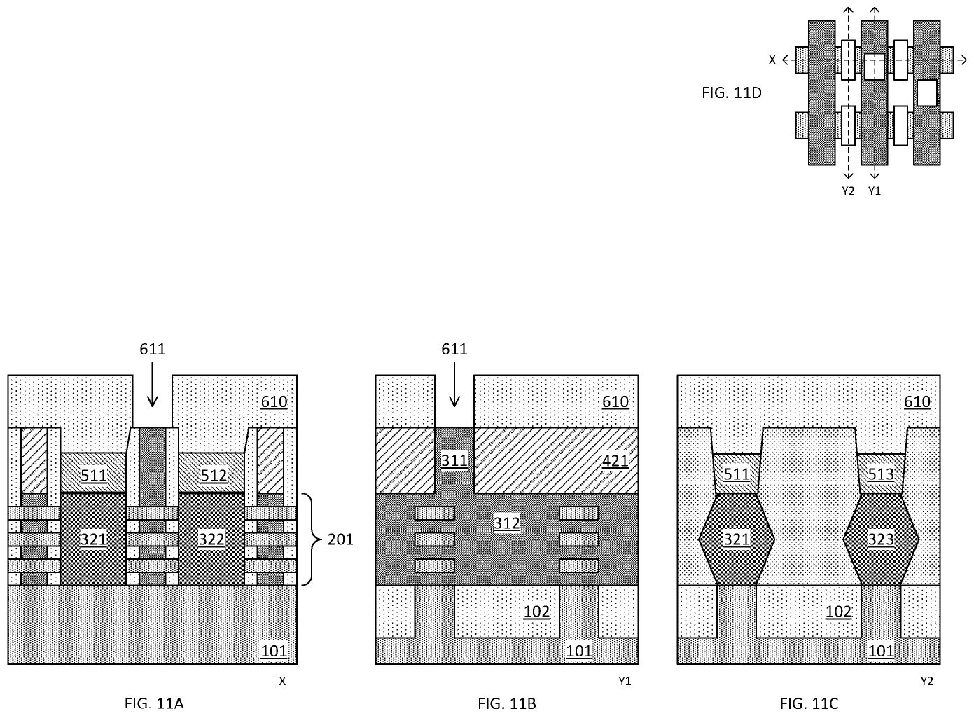

FIGS. 11A, 11B, 11C, and 11D are demonstrative illustrations of different cross-sectional views and schematic top view of the semiconductor structure 10 in a step of manufacturing thereof according to one embodiment of present invention. More particularly, following the step illustrated in FIGS. 10A, 10B, 10C, and 10D, embodiments of present invention provide removing the dummy gate contact 410, in a selectively etching process, to create a gate contact opening 611 in the dielectric layer 610. As is described above, because the dummy gate contact 410 was used in the etching process to create the first portion 311 of the gate structure 310, the gate contact opening 611 is substantially aligned with, and exposes the first portion 311 of the gate structure 310. The gate contact opening 611 creates a template for forming a self-aligned gate contact.

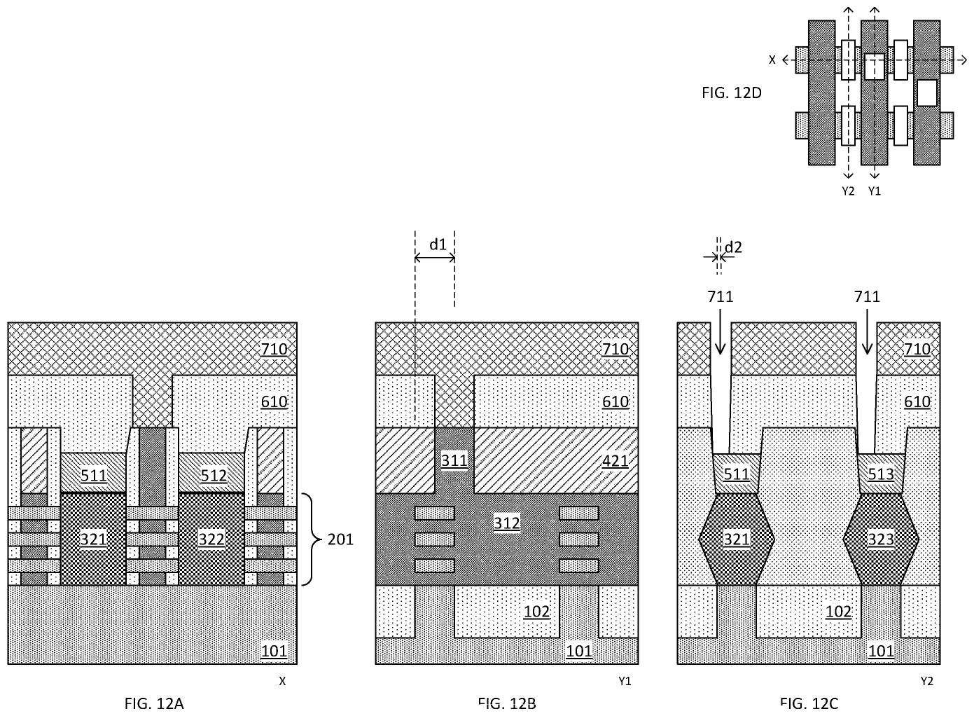

FIGS. 12A, 12B, 12C, and 12D are demonstrative illustrations of different cross-sectional views and schematic top view of the semiconductor structure 10 in a step of manufacturing thereof according to one embodiment of present invention. More particularly, following the step illustrated in FIGS. 11A, 11B, 11C, and 11D, embodiments of present invention provide forming an OPL 710 on top of the dielectric layer 610. The OPL 710 may fill the gate contact opening 611 that exposes the first portion 311 of the gate structure 310. The OPL 710 may then be patterned to create openings for forming via contacts. For example, via openings 711 may first be created in the OPL 710 through, for example, a lithographic patterning process and may be further transferred to the underneath dielectric layer 610 through an anisotropic and/or directional etching process until a portion of the source/drain contact 511 and/or 513 is exposed.

In one embodiment, a central axis of the via opening 711 may have an offset d2 in distance from the longitudinal edge of the set of nanosheets 201 as compared with the offset d1 with regard to the dummy gate contact 410 as being described above with reference to FIG. 3B, with the offset d1 being reproduced here in FIG. 12B. For example, the via opening 711 may be placed asymmetric with respect to the set of nanosheets 201. As is illustrated in FIG. 12C, the via opening 711 may be placed more towards the left-side of the set of nanosheets 201. In one embodiment, the cross-section of the via opening 711 does not overlap with the cross-section of the dummy gate contact 410 along a direction of the gate structure 310.

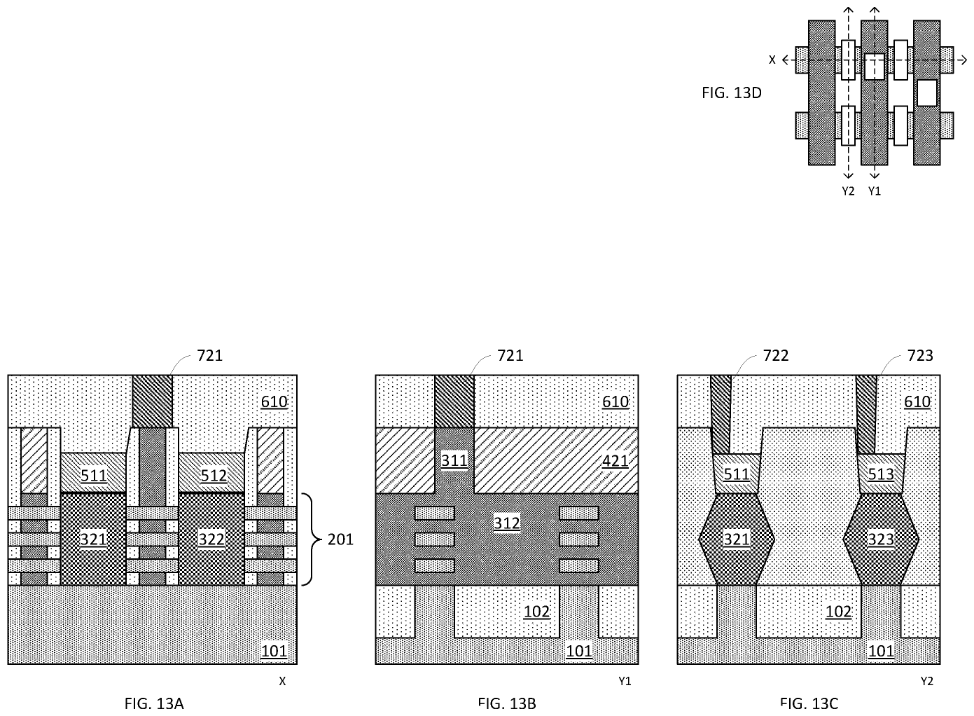

FIGS. 13A, 13B, 13C, and 13D are demonstrative illustrations of different cross-sectional views and schematic top view of the semiconductor structure 10 in a step of manufacturing thereof according to one embodiment of present invention. More particularly, following the step illustrated in FIGS. 12A, 12B, 12C, and 12D, embodiments of present invention provide lifting or removing the OPL 710 through an ash process to expose the opening 611 above first portion 311 of the gate structure 310, together with the via opening 711, and subsequently filling the gate contact opening 611 and the via opening 711 with a conductive material to form a gate contact 721 and via contacts 722 and 723. The gate contact 721 contacts the gate structure 310 through the first portion 311 thereof, and the via contacts 722 and 723 contact the source/drain contacts 511 and 513.

In one embodiment, the gate contact 721 and the via contact 722 may have different offsets from the longitudinal edge of the set of nanosheets 201. Additionally, cross-sections of the gate contact 721 and the via contact 722, made perpendicular to a length direction of the gate structure 310, do not overlap with each other. In other words, they do not overlap in the length direction of the gate structure 310 and/or in the longitudinal direction of the set of nanosheets 201.

A CMP process may subsequently be applied to planarize the gate contact 721 and the via contacts 722 and 723 such that a top surface of the gate contact 721 may be coplanar with a top surface of the via contact 722 and/or a top surface of the via contact 723.

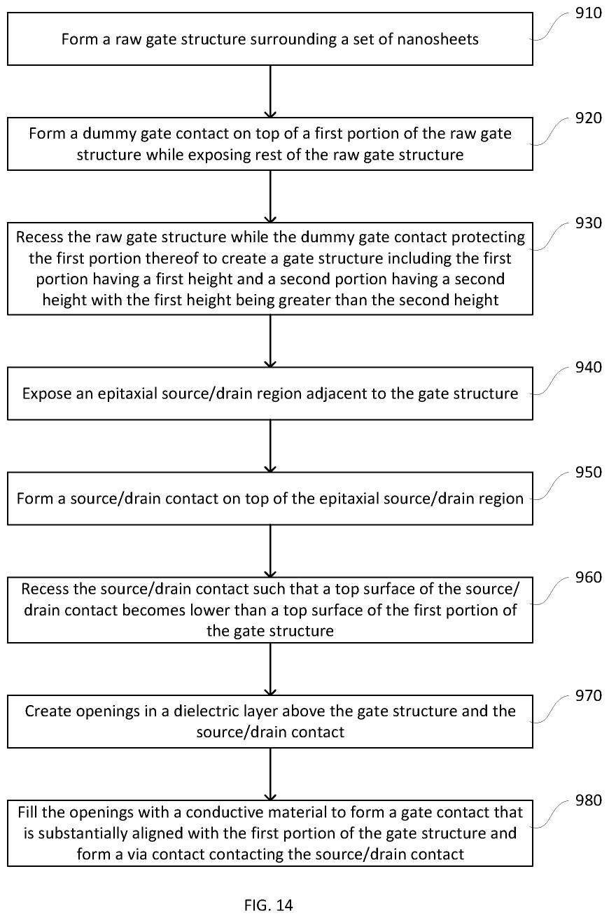

FIG. 14 is a demonstrative illustration of a flow-chart of a method of manufacturing a semiconductor structure according to embodiments of present invention. The method includes (910) forming a raw gate structure surrounding a set of nanosheets of a semiconductor structure; (920) form a dummy gate contact on top of a first portion of the raw gate structure while exposing rest of the raw gate structure; (930) recessing the raw gate structure while the dummy gate contact protecting the first portion thereof to create a gate structure, the gate structure including the first portion having a first height and a second portion having a second height, with the first height being greater than the second height; (940) exposing an epitaxial source/drain region adjacent to the gate structure; (950) forming a source/drain contact on top of the epitaxial source/drain region; (960) recessing the source/drain contact such that a top surface of the source/drain contact becomes lower than a top surface of the first portion of the gate structure; (970) creating openings in a dielectric layer above the gate structure and the source/drain region; and (980) filling the openings with a conductive material to form a gate contact that is substantially aligned with the first portion of the gate structure and form a via contact contacting the source/drain contact.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a gate structure with a first portion having a first top surface and a second portion having a second top surface, the first top surface being above the second top surface;
a dielectric cap layer on top of the second portion of the gate structure, the first portion of the gate structure being embedded in the dielectric cap layer; and
a gate contact being above and substantially aligned with the first portion of the gate structure.

2. The semiconductor structure of claim 1, further comprising a source/drain contact adjacent to the gate structure, wherein the source/drain contact has a top surface that is below the first top surface of the first portion of the gate structure.

3. The semiconductor structure of claim 2, further comprising a sidewall spacer at a sidewall of the gate structure and in between the gate structure and the source/drain contact, wherein a height of the sidewall spacer is greater than a height of the source/drain contact.

4. The semiconductor structure of claim 3, wherein an upper portion of the sidewall spacer above the source/drain contact has a non-uniform thickness.

5. The semiconductor structure of claim 3, further comprising a via contact contacting the top surface of the source/drain contact, wherein a top surface of the via contact is coplanar with a top surface of the gate contact.

6. The semiconductor structure of claim 5, wherein the gate structure surrounds a set of nanosheets, and the source/drain contact is above an epitaxial source/drain region formed at an end of the set of nanosheets.

7. The semiconductor structure of claim 5, wherein cross-sections of the via contact and the gate contact, made perpendicular to a length direction of the gate structure, do not overlap with each other.

8. A semiconductor device comprising:
a set of nanosheets;
a gate structure surrounding the set of nanosheets, the gate structure having a first portion of a first height and a second portion of a second height, the first height being greater than the second height;
a dielectric cap layer on top of the second portion of the gate structure, the first portion of the gate structure being embedded in the dielectric cap layer; and
a gate contact being above and substantially aligned with the first portion of the gate structure.

9. The semiconductor device of claim 8, further comprising a first and a second epitaxial source/drain region at a first and a second end of the set of nanosheets.

10. The semiconductor device of claim 9, further comprising a first and a second source/drain contact above the first and the second epitaxial source/drain region respectively and the first and the second source/drain contact being adjacent to the gate structure, wherein at least a top surface of the first source/drain contact is below a top surface of the first portion of the gate structure.

11. The semiconductor device of claim 10, further comprising a sidewall spacer between the gate structure and the first source/drain contact, wherein the first source/drain contact has a height that is smaller than a height of the sidewall spacer.

12. The semiconductor device of claim 11, wherein a lower portion of the sidewall spacer directly between the first source/drain region and the gate structure has a uniform thickness.

13. The semiconductor device of claim 11, further comprising a via contact contacting the top surface of the first source/drain contact, wherein a top surface of the via contact is coplanar with a top surface of the gate contact.

14. The semiconductor device of claim 13, wherein the via contact and the gate contact have different offsets from a longitudinal edge of the set of nanosheets.

15. A method of forming a semiconductor structure comprising:
forming a raw gate structure surrounding a set of nanosheets;
recessing a portion of the raw gate structure to create a gate structure, the gate structure including a first portion having a first height and a second portion having a second height, the first height being greater than the second height;
exposing an epitaxial source/drain region adjacent to the gate structure;
forming a source/drain contact on top of the epitaxial source/drain region;
recessing the source/drain contact such that a top surface of the source/drain contact becomes lower than a top surface of the first portion of the gate structure;
forming a gate contact contacting the first portion of the gate structure; and
forming a via contact contacting the source/drain contact.

16. The method of claim 15, further comprising forming a dummy gate contact on top of the first portion of the gate structure, the dummy gate contact protecting the first portion of the gate structure while recessing the portion of the raw gate structure to create the gate structure.

17. The method of claim 16, wherein forming the gate contact comprises:
embedding the dummy gate contact in a dielectric layer;
removing the dummy gate contact to create an opening in the dielectric layer; and
filling the opening with a conductive material to form the gate contact.

18. The method of claim 16, wherein exposing the epitaxial source/drain region comprises selectively removing an interlevel dielectric layer on top of the epitaxial source/drain region, the selectively removing resulting in an upper portion of a sidewall spacer, at a sidewall of the gate structure, that has a non-uniform thickness.

19. The method of claim 18, wherein recessing the source/drain contact comprises lowering the top surface of the source/drain contact such that a resulting source/drain contact is adjacent to a lower portion of the sidewall spacer that has a uniform thickness.

20. The method of claim 16, wherein the via contact and the gate contact have different offsets from a longitudinal edge of the set of nanosheets, and cross-sections of the gate contact and the via contact do not overlap with each other.
